(19) United States
(12) Patent Application Publication
(10) Pub. No.: US 2020/0161103 A1
(43) Pub. Date: May 21, 2020

(54) ELECTROSTATIC CHUCK AND PLASMA PROCESSING APPARATUS

(71) Applicant: BEIJING NAURA MICROELECTRONICS EQUIPMENT CO., LTD., Beijing (CN)

(72) Inventor: Jian LIU, Beijing (CN)

(21) Appl. No.: 16/630,793

(22) PCT Filed: Oct. 12, 2017
(86) PCT No.: PCT/CN2017/105838

§ 371 Date: Jan. 13, 2020

(30) Foreign Application Priority Data
Jul. 17, 2017 (CN) 201710580505.3

(51) Int. Cl. H01J 37/32; H01L 21/683; H01L 21/67

(52) U.S. Cl. CPC H01J 37/32724; H01L 21/6833; H01J 2237/2001; H01L 21/67069; H01J 2237/334; H01J 37/32651

(57) ABSTRACT

The present disclosure provides an electrostatic chuck and a plasma processing apparatus. The electrostatic chuck includes: a base; a heating layer disposed on the base; an insulating layer disposed on the heating layer; and an annular-shaped protection member surrounding an outer peripheral wall of the heating layer and detachably disposed on an outer side of the heating layer. An outer diameter of the heating layer is smaller than both an outer diameter of the base and an outer diameter of the insulating layer. The electrostatic chuck and the plasma processing apparatus provided by the present disclosure not only protects the heating layer during the manufacturing process, but also can be separately replaced when the annular-shaped protection member is damaged. The heating layer is unaffected during the replacement process. Thus, the electrostatic chuck has the characteristics of long lifespan, and low maintenance and replacement cost, etc.

### FIELD OF THE DISCLOSURE

The present disclosure generally relates to the technical field of semiconductor manufacturing process and, more particularly, relates to an electrostatic chuck and a plasma processing apparatus.

### BACKGROUND

In an integrated circuit (IC) manufacturing process, especially in a plasma etching process, an electrostatic chuck (ESC) is often used to hold and support a wafer, to avoid the shifting or misaligning of the wafer during the manufacturing process, and to simultaneously control a temperature of the wafer.

FIG. 1 illustrates a schematic view of an existing electrostatic chuck. As shown in FIG. 1, the electrostatic chuck includes a base 1, a heating layer 2 disposed on the base 1, and an insulating layer 3 disposed on the heating layer 2. Moreover, a silicone material 4 is coated on an outer peripheral wall of the heating layer 2. The silicone material coat is disposed between the base 1 and the insulating layer 3 to protect the heating layer 2 from being etched by a plasma.

The above described electrostatic chuck inevitably has the following problems in practical applications.

After being etched by the plasma, the silicone material 4 gets thinner and thinner until it completely disappears. The heating layer 2 is no longer protected by the silicone material 4, such that the heating layer 2 is directly exposed in a plasma environment. The heating layer 2 is likely to be corroded to produce particles polluting the wafer, thereby reducing wafer quality. Because the silicone material 4 is coated on the outer peripheral wall of the heating layer 2, the residual silicone material must be removed before the new silicone material 4 can be re-coated. The process not only is difficult to perform, but also is likely to damage the heating layer 2 as well as the electrostatic chuck. Thus, in a common practice, after the silicone material 4 is thinned by the plasma etching to a certain extent, the electrostatic chuck will be discarded and replaced with a new electrostatic chuck, thereby causing a substantial waste.

### BRIEF SUMMARY OF THE DISCLOSURE

The objective of the present disclosure is to solve one or more technical problems in the existing technology. The present disclosure provides an electrostatic chuck and a plasma processing apparatus having the characteristics of long lifespan, and low maintenance and replacement cost, etc.

One aspect of the present disclosure provides an electrostatic chuck including: a base; a heating layer disposed on the base; an insulating layer disposed on the heating layer; and an annular-shaped protection member surrounding an outer peripheral wall of the heating layer and detachably disposed on an outer side of the heating layer. An outer diameter of the heating layer is smaller than both an outer diameter of the base and an outer diameter of the insulating layer.

Optionally, the annular-shaped protection member is elastic; a height of the uncompressed and undeformed annular-shaped protection member in a vertical direction is greater than or equal to a gap between the base and the insulating layer; and when being assembled between the base and the insulating layer, the annular-shaped protection member is capable of blocking the heating layer from a plasma.

Optionally, the height of the uncompressed and undeformed annular-shaped protection member in the vertical direction is greater than or equal to the gap between the base and the insulating layer; and when being assembled between the base and the insulating layer, the annular-shaped protection member is compressed and deformed to block the heating layer from the plasma.

Optionally, when the annular-shaped protection member is not compressed or deformed, a cross-sectional shape of the annular-shaped protection member in a plane where a central axis of the electrostatic chuck is located is a rectangle, a square, a trapezoid, a circle, or an ellipse.

Optionally, when the cross-sectional shape is the rectangle, the square, or the trapezoid, any two adjacent sides of the rectangle, the square, or the trapezoid adopt a rounded corner transition.

Optionally, a radius of the rounded corner ranges approximately between 1 mm and 3 mm.

Optionally, a cross-sectional shape of the annular-shaped protection member in a plane where a central axis of the electrostatic chuck is located is a circle; and a height of an annular space formed between the outer peripheral wall of the heating layer, an upper surface of the base, and a lower surface of the insulating layer in an axial direction of the electrostatic chuck is smaller than about 90% of a diameter of the cross-sectional shape.

Optionally, the cross-sectional shape is the rectangle, the square, or the trapezoid; and an outer annular surface of the annular-shaped protection member is a concave surface.

Optionally, a minimum thickness of the annular-shaped protection member in a radial direction is greater than or equal to about 80% of a maximum thickness of the annular-shaped protection member in the radial direction.

Optionally, the cross-sectional shape of the concave outer annular surface of the annular-shaped protection member is an arc, a diagonal line, or a folded line; the folded line extends in the vertical direction and includes at least two line segments; any two adjacent line segments of the at least two line segments are connected; and an angle formed between any two adjacent line segments is an acute angle, a right angle, or an obtuse angle.

Optionally, the annular-shaped protection member includes an annular-shaped body; the annular-shaped body is disposed between the base and the insulating layer, and surrounds the outer peripheral wall of the heating layer; a height of the uncompressed and undeformed annular-shaped protection member in a vertical direction is greater than or equal to a gap between the base and the insulating layer; at least one annular-shaped extension portion is formed on an outer peripheral wall of the annular-shaped body; when the number of the at least one annular-shaped extension portion is one, the annular-shaped extension portion extends upward on the outer peripheral wall of the annular-shaped body and covers an outer peripheral wall of the insulating layer with a top end of the annular-shaped extension portion not higher than an upper surface of the insulating layer, or extends downward on the outer peripheral wall of the annular-shaped body and covers an outer peripheral wall of the base; and when the number of the at least one annular-shaped extension portion is two, an upper half of the annular-shaped extension portion extends upward on the outer peripheral wall of the annular-shaped body and covers the outer peripheral wall of the insulating layer with the top end thereof not higher than the upper surface of the insulating layer, and a lower half of the annular-shaped extension portion extends downward on the outer peripheral wall of the annular-shaped body and covers the outer peripheral wall of the base.

Optionally, the annular-shaped protection member is made of a perfluoro rubber.

Another aspect of the present disclosure provides a plasma processing apparatus including a processing chamber. The disclosed electrostatic chuck is configured inside the processing chamber.

The present disclosure has the following beneficial effects.

In the electrostatic chuck provided by the embodiments of the present disclosure, the annular-shaped protection member and the heating layer are two structures independent of each other. The annular-shaped protection member surrounds the outer peripheral wall of the heating layer and is detachably disposed on the outer side of the heating layer. As such, the annular-shaped protection member not only protects the heating layer during the manufacturing process, but also can be separately replaced when the annular-shaped protection member is damaged. The heating layer is unaffected during the replacement process, thereby extending the lifespan of the electrostatic chuck and saving the apparatus cost.

The present disclosure provides a plasma processing apparatus, which includes the above referenced electrostatic chuck. The annular-shaped protection member and the heating layer of the electrostatic chuck are two structures independent of each other. The annular-shaped protection member surrounds the outer peripheral wall of the heating layer and is detachably disposed on the outer side of the heating layer. As such, the annular-shaped protection member not only protects the heating layer during the manufacturing process, but also can be separately replaced when the annular-shaped protection member is damaged. The heating layer is unaffected during the replacement process, thereby extending the lifespan of the electrostatic chuck and saving the apparatus cost.

### BRIEF DESCRIPTION OF THE DRAWINGS

FIG. 1 illustrates a schematic view of an existing electrostatic chuck.

FIG. 2 illustrates a partial cross-sectional view of an electrostatic chuck according to a first embodiment of the present disclosure;

FIG. 3 illustrates a top view of an electrostatic chuck according to a the first embodiment of the present disclosure;

FIG. 4 illustrates a partial cross-sectional view of an electrostatic chuck according to a first modified embodiment of the first embodiment of the present disclosure;

FIG. 5 illustrates a partial cross-sectional view of another exemplary electrostatic chuck according to a second modified embodiment of the first embodiment of the present disclosure;

FIG. 6 illustrates a partial cross-sectional view of another exemplary electrostatic chuck according to a third modified embodiment of the first embodiment of the present disclosure;

FIG. 7 illustrates a partial cross-sectional view of another exemplary electrostatic chuck according to a fourth modified embodiment of the first embodiment of the present disclosure;

FIG. 8 illustrates a partial cross-sectional view of another exemplary electrostatic chuck according to a fifth modified embodiment of the first embodiment of the present disclosure;

FIG. 9 illustrates a partial cross-sectional view of another exemplary electrostatic chuck according to a second embodiment of the present disclosure;

FIG. 10 illustrates a partial cross-sectional view of another exemplary electrostatic chuck according to a first modified embodiment of the second embodiment of the present disclosure; and

FIG. 11 illustrates a partial cross-sectional view of another exemplary electrostatic chuck according to a second modified embodiment of the second embodiment of the present disclosure.

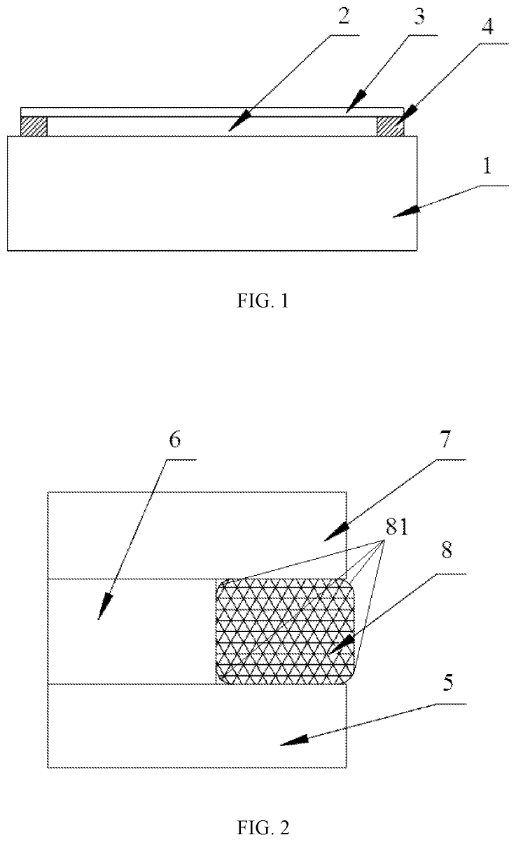

### DETAILED DESCRIPTION

To make those skilled in the art better understand the present disclosure, the following describes an electrostatic chuck provided by the embodiments of the present disclosure in details with reference to the accompanying drawings.

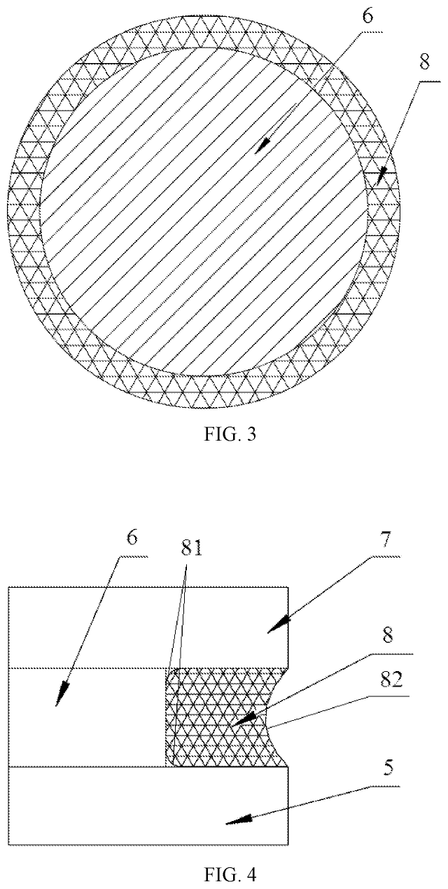

Referring to FIG. 2 and FIG. 3, the electrostatic chuck includes a base 5, a heating layer 6 disposed on the base 5, and an insulating layer 7 disposed on the heating layer 6. A heating element is configured in the heating layer 6 as a heat source. The heat is transferred to a wafer supported by the electrostatic chuck through the insulating layer 7. The insulating layer 7 is made of a ceramic material such as Al₂O₃ and AIN or other insulating materials. Moreover, a direct current (DC) electrode layer is disposed in the insulating layer 7. An electrostatic force is generated between the DC electrode layer and the wafer placed on the insulating layer, thereby achieving the objective of fixing the wafer.

Moreover, the electrostatic chuck also includes an annular-shaped protection member 8. The annular-shaped protection member 8 is detachably configured on an outer peripheral wall of the heating layer 6. That is, the heating layer 6 is located inside the annular hole of the annular-shaped protection member 8. Whether the heating layer 6 and the annular-shaped protection member 8 contact with each other or not (i.e., whether there is a gap in between) is not limited by the present disclosure. The annular-shaped protection member 8 may be separated from the heating layer 6 without damaging the heating layer 6. Being detachable refers to that the annular-shaped protection member 8 and the heating layer 6 are two structures independent of each other. The damaged annular-shaped protection member 8 may be separately replaced. Replacing the annular-shaped protection member 8 will not damage the heating layer 6, thereby extending a lifespan of the electrostatic chuck and saving process and apparatus costs.

Preferably, to better protect the heating layer 6 inside the annular-shaped protection member 8 from being etched by the plasma, the annular-shaped protection member 8 is elastic, and is compressed and deformed between the base 5 and the insulating layer 7. That is, a gap between the base 5 and the insulating layer 7 is smaller than or equal to a height of the uncompressed and undeformed annular-shaped protection member 8 in a vertical direction (i.e., an axial direction). As such, the gap in the vertical direction between the base 5 and the insulating layer 7 is blocked and the plasma cannot pass through the gap to reach a peripheral surface of the heating layer 6, thereby achieving separation between the heating layer 6 and the plasma. When being assembled, the annular-shaped protection member 8 may be compressed first in the vertical direction, such that the height of the compressed annular-shaped protection member 8 in the vertical direction is smaller than the gap in the vertical direction between the base 5 and the insulating layer 7. Then, the compressed annular-shaped protection member 8 is enclosed on the peripheral wall of the heating layer 6 and inserted into the gap between the base 5 and the insulating layer 7. The annular-shaped protection member 8 remains compressed and deformed, such that the annular-shaped protection member 8 can be in close contact with the base 5 and the insulating layer 7, thereby sealing the gap. While achieving the detachability, the elastic annular-shaped protection member 8 may seal the gap between the base 5 and the insulating layer 7, separate the heating layer 6 from the plasma, and avoid polluting the wafer by the particles generated from the corrosion of the heating layer 6 exposed directly in the plasma environment. Thus, the wafer processing quality is improved.

Preferably, the material of the annular-shaped protection member 8 includes a perfluoro rubber. The perfluoro rubber not only is elastic, but also is heat resistant, oxidation resistant, corrosion resistant, and aging resistant due to introducing fluorine atoms into the rubber.

In one embodiment, when the annular-shaped protection member 8 is not compressed or deformed, a cross-sectional shape in a plane where a central axis of the electrostatic chuck is located (hereinafter simply referred to as the cross-sectional shape) is a rectangle, as shown in FIG. 2. Preferably, any two adjacent surfaces of the annular-shaped protection member 8 adopt a rounded corner 81 transition. That is, a circular chamfer transition is configured between any two adjacent sides of the rectangle for easy assembling and avoiding damages during assembling and disassembling. Further preferably, a radius of the rounded corner 81 ranges approximately between 1 mm and 3 mm for easy assembling. In practical applications, the cross-sectional shape may also be a square or a trapezoid. In fact, any shapes that can block the gap between the base 5 and the insulating layer 7 and protect the heating layer 6 from being etched by the plasma may be used.

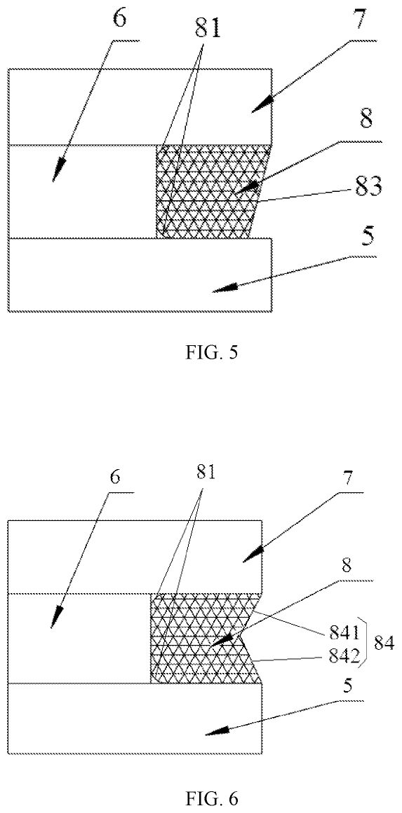

Preferably, an outer annular surface of the annular-shaped protection member 8 may be a concave surface, which is beneficial for preventing the annular-shaped protection member 8 from contacting with adjacent components. For example, the outer annular surface of the annular-shaped protection member 8 that has a rectangular or square cross-sectional shape is configured to be concave. Specifically, as shown in FIG. 4, the cross-sectional shape of the concave shape is an arc 82. Alternatively, as shown in FIG. 5, the cross-sectional shape of the concave shape is a diagonal line 83. That is, the cross-sectional shape of the annular-shaped protection member 8 is a right-angled trapezoid. In one embodiment, the diagonal line 83 is tilted downward. That is, the upper base of the trapezoid is longer than the lower base of the trapezoid. In practical applications, the diagonal line 83 may be tilted upward. That is, the lower base of the trapezoid is longer than the upper base of the trapezoid. In addition, the trapezoid may not be limited to the right-angled trapezoid.

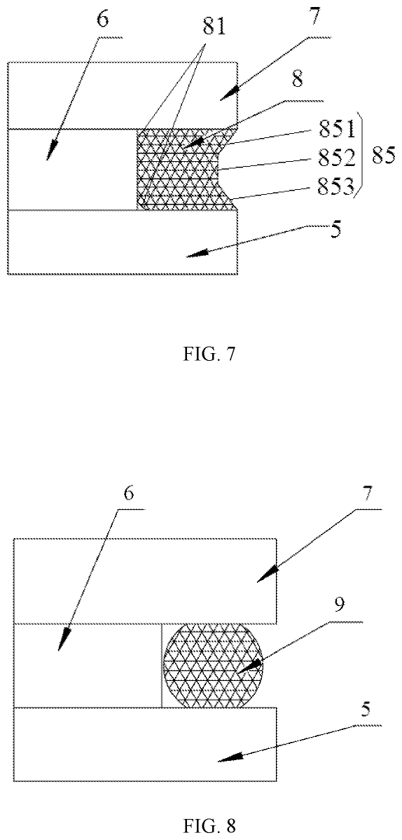

As shown in FIG. 6, the cross-sectional shape of the concave outer annular surface of the annular-shaped protection member 8 is a folded line 84. The folded line 84 includes two connected line segments (841, 842) in the vertical direction. An angle is formed between the two line segments (841, 842). The angle may be an acute angle, a right angle, or an obtuse angle. Alternatively, as shown in FIG. 7, the concave cross-sectional shape is another folded line 85. The folded line 85 includes three connected line segments (851, 852, 853). An angle is formed between any two adjacent line segments. The angle may be an acute angle, a right angle, or an obtuse angle. In practical applications, the folded line may include four, five or more line segments. In other words, the folded line extends in the vertical direction and includes at least two line segments. Any two adjacent line segments of the at least two line segments are connected. The angle formed between any two adjacent line segments may be an acute angle, a right angle, or an obtuse angle.

Preferably, in addition to the concave outer annular surface of the annular-shaped protection member 8, a minimum thickness of the annular-shaped protection member 8 in a radial direction is greater than or equal to about 80% of a maximum thickness of the annular-shaped protection member 8 in the radial direction, thereby increasing the lifespan of the annular-shaped protection member 8 and ensuring the desired sealing effect thereof.

It should be noted that, in one embodiment, when the annular-shaped protection member 8 is not compressed or deformed, the cross-sectional shape in the plane where the central axis of the electrostatic chuck is located may be a rectangle, a square, or a trapezoid. However, the embodiments of the present disclosure do not limit the cross-sectional shape. In practical applications, the cross-sectional shape may also be a circle.

Preferably, when the cross-sectional shape is the circle, a height of an annular space formed between the outer peripheral wall of the heating layer 6, an upper surface of the base 5, and a lower surface of the insulating layer 7 in the axial direction of the electrostatic chuck is smaller than about 90% of a diameter of the cross-sectional shape, thereby ensuring the desired sealing effect thereof. In addition, in practical applications, a length of the annular space in the radial direction is desired to be larger than a diameter of the uncompressed and undeformed annular-shaped protection member 8. As such, the annular-shaped protection member is ensured to be contained within the outer periphery of the insulating layer 7 or the base 5 when the annular-shaped protection member 8 is compressed or deformed, and the annular-shaped protection member 8 is prevented from contacting with the adjacent components.

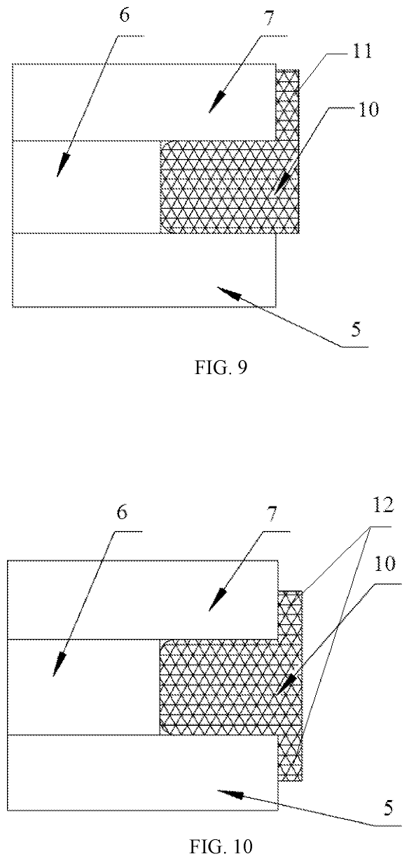

FIG. 9 illustrates a partial cross-sectional view of another exemplary electrostatic chuck according to some embodiments of the present disclosure. Referring to FIG. 9, in one embodiment, compared with the previous embodiments, the electrostatic chuck includes an annular-shaped extension portion to further improve the sealing effect of the annular-shaped protection member.

Specifically, in one embodiment, the annular-shaped protection member includes an annular-shaped body 10. The annular-shaped body 10 surrounds the outer peripheral wall of the heating layer 6 and is disposed between the base 5 and the insulating layer 7. The annular-shaped body 10 is compressed and deformed between the base 5 and the insulating layer 7. For example, the annular-shaped body 10 is compressed and deformed at least in the vertical direction. That is, a height of the uncompressed and undeformed annular-shaped body 10 in the vertical direction is greater than the gap between the base 5 and the insulating layer 7. The annular-shaped body 10 seals the gap between the base 5 and the insulating layer 7, separates the heating layer 6 from the plasma, prevents the heating layer 6 from being corroded and producing particles due to a direct exposure to the plasma environment, and improves the wafer processing quality. A thickness of the annular-shaped body 10 in the radial direction is greater than a distance between the outer peripheral wall of the heating layer 6 and the outer peripheral wall of the insulating layer 7 to ensure that even if the annular-shaped body 10 is compressed and deformed in the radial direction, the thickness of the annular-shaped body 10 in the radial direction is greater than the distance between the outer peripheral wall of the heating layer 6 and the outer peripheral wall of the insulating layer 7. That is, the outer peripheral wall of the annular-shaped body 10 extends outside the outer peripheral wall of the insulating layer 7.

Moreover, the annular-shaped protection member also includes a first annular-shaped extension portion 11. The first annular-shaped extension portion 11 extends upward from an upper surface of a protrusion of the annular-shaped body 10, surrounds the outer peripheral wall of the insulating layer 7, and covers and bonds to the outer peripheral wall of the insulating layer 7 to enhance the sealing effect of the gap between the annular-shaped body 10 and the insulating layer 7 and at the same time to prevent the bonded and covered insulating layer 7 from being corroded by the plasma. Further, a top end of the first annular-shaped extension portion 11 does not exceed an upper surface of the insulating layer 7 to avoid affecting the wafer on the insulating layer 7 during the process. Preferably, the top end of the first annular-shaped extension portion 11 is lower than the upper surface of the insulating layer 7. A height of the first annular-shaped extension portion 11 bonding and covering the outer peripheral wall of the insulating layer 7 is approximately between 1 mm and 10 mm. It should be noted that the bonding and covering refers to that no gap exists between the first annular-shaped extension portion 11 and the insulating layer 7 to allow the plasma to pass through, which is hereinafter referred to as the covering. The protrusion of the annular-shaped body 10 refers to a portion of the assembled annular-shaped body 10 that protrudes outside the outer peripheral wall of the insulating layer 7 in the radial direction, regardless of whether the annular-shaped body 10 is compressed or not in the radial direction.

Alternatively, as shown in FIG. 10, a second annular-shaped extension portion 12 is also formed on the outer peripheral wall of the annular-shaped body 10. An upper half of the second annular-shaped extension portion 12 extends upward from the upper surface of the protrusion of the annular-shaped body 10, surrounds the outer peripheral wall of the insulating layer 7, and covers the outer peripheral wall of the insulating layer 7 to enhance the sealing effect of the gap between the annular-shaped body 10 and the insulating layer 7 and to prevent the covered insulating layer 7 from being corroded by the plasma. At the same time, a lower half of the second annular-shape extension portion 12 extends downward from the lower surface of the protrusion of the annular-shaped body 10, surrounds the outer peripheral wall of the base 5, and covers the outer peripheral wall of the base 5 to enhance the sealing effect of the gap between the annular-shaped body 10 and the base 5 and to prevent the covered base 5 from being corroded by the plasma. A height on the outer peripheral wall of the insulating layer 7 covered by the upper half of the second annular-shaped extension portion 12 may be approximately between 1 mm and 10 mm, and a height on the outer peripheral wall of the base 5 covered by the lower half of the second annular-shaped extension portion 12 may be approximately between 1 mm and 10 mm. In one embodiment, the orthogonal projections of the outer peripheral wall of the insulating layer 7 and the outer peripheral wall of the base 5 on a plane perpendicular to the central axis of the electrostatic chuck overlap with each other. That is, the diameters of the outer peripheral wall of the insulating layer 7 and the outer peripheral wall of the base 5 are equal. Further, the thicknesses of the upper half and the lower half of the second annular-shaped extension portion 12 are the same. That is, the orthogonal projections of the inner peripheral wall and the outer peripheral wall of the upper half of the second annular-shaped extension portion 12 on the plane perpendicular to the central axis of the electrostatic chuck respectively coincide with the orthogonal projections of the inner peripheral wall and the outer peripheral wall of the lower half of the second annular-shaped extension portion 12 on the same plane. However, in practical applications, the diameters of the outer peripheral wall of the insulating layer 7 and the outer peripheral wall of the base 5 may not be equal. In this case, the outer peripheral wall having a smaller diameter of both the insulating layer 7 and the base 5 is used as the reference for defining the protrusion of the annular-shaped body 10. That is, the protrusion of the annular-shaped body 10 refers to the portion of the annular-shaped body 10 protruding in the radial direction relative to the outer peripheral wall having the smaller diameter of both the insulating layer 7 and the base 5. As such, to ensure that the upper half and the lower half of the second annular-shaped extension portion 12 are able to bond and cover the outer peripheral walls of the insulating layer 7 and the base 5, respectively, the orthogonal projections of the inner peripheral walls of the upper half and the lower half of the second annular-shaped extension portion 12 on the plane perpendicular to the central axis of the electrostatic chuck may not overlap with each other. Further, the orthogonal projections of the outer peripheral walls of the upper half and the lower half of the second annular-shaped extension port 12 on the same plane may or may not coincide with each other, which is not limited by the present disclosure. It should be noted that, when the annular-shaped protection member includes the second annular-shaped extension portion 12 as shown in FIG. 10, the height of the uncompressed and unformed annular-shaped body 10 is no longer required to be greater than or equal to the gap between the insulating layer 7 and the base 5.

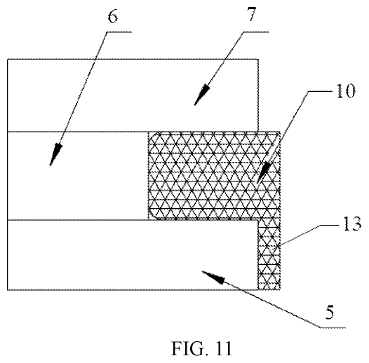

Alternatively, as shown in FIG. 11, a third annular-shaped extension portion 13 is also formed on the outer peripheral wall of the annular-shaped body 10. The third annular-shaped extension portion 13 extends downward from the lower surface of the protrusion of the annular-shaped body 10, surrounds the outer peripheral wall of the base 5, and covers the outer peripheral wall of the base 5 to enhance the sealing effect of the gap between the annular-shaped body 10 and the base 5 and to prevent the covered base 5 from being corroded by the plasma. A height on the outer peripheral wall of the base 5 covered by the third annular-shaped extension portion 13 may be approximately between 1 mm and 10 mm.

As can be seen from the above, at least one annular-shaped extension port may be formed on the outer peripheral wall of the annular-shaped body 10. The annular-shaped extension portion may cover only the outer peripheral wall of the insulating layer 7, or only the outer peripheral wall of the base 5, or the outer peripheral walls of both the insulating layer 7 and the base 5. Moreover, when the annular-shaped protection member includes the annular-shaped body 10 and the annular-shaped extension portion, the height of the uncompressed and undeformed annular-shaped body 10 is considered as the height of the uncompressed and undeformed annular-shaped protection member.

Further, in the electrostatic chuck provided by the embodiments of the present disclosure, the annular-shaped protection member and the heating layer are two structures independent of each other. The annular-shaped protection member surrounds the outer peripheral wall of the heating layer and is detachably disposed on the outer side of the heating layer. As such, the annular-shaped protection member not only protects the heating layer during the manufacturing process, but also can be separately replaced when the annular-shaped protection member is damaged. The heating layer is unaffected during the replacement process, thereby extending the lifespan of the electrostatic chuck and saving the apparatus cost. Thus, the electrostatic chuck provided by the embodiments of the present disclosure has the characteristics of long lifespan, and low maintenance and replacement cost, etc.

Further, the present disclosure also provides a plasma processing apparatus. The plasma processing apparatus includes a processing chamber. The electrostatic chuck provided by the embodiments of the present disclosure is configured inside the processing chamber.

In the plasma processing apparatus provided by the embodiments of the present disclosure, because the annular-shaped protection member and the heating layer of the electrostatic chuck are two structures independent of each other, the annular-shaped protection member surrounds the outer peripheral wall of the heating layer and is detachably disposed on the outer side of the heating layer. As such, the annular-shaped protection member not only protects the heating layer during the manufacturing process, but also can be separately replaced when the annular-shaped protection member is damaged. The heating layer is unaffected during the replacement process, thereby extending the lifespan of the electrostatic chuck and saving the apparatus cost.

It should be understood that the above embodiments are merely exemplary to illustrate the operation principles. However, the present disclosure is not limited to the specific embodiments described herein. Various modifications and improvements will occur to those skilled in the art without departing from the spirit and scope of the present disclosure. These modifications and improvements are also considered to be within the scope of the present disclosure.

1. An electrostatic chuck, comprising:
a base;
a heating layer disposed on the base;
an insulating layer disposed on the heating layer; and
an annular-shaped protection member surrounding an outer peripheral wall of the heating layer and detachably disposed on an outer side of the heating layer, wherein an outer diameter of the heating layer is shorter than both an outer diameter of the base and an outer diameter of the insulating layer.

2. The electrostatic chuck according to claim 1, wherein:
the annular-shaped protection member is elastic;
a height of the uncompressed and undeformed annular-shaped protection member in a vertical direction is greater than or equal to a gap between the base and the insulating layer; and
when being assembled between the base and the insulating layer, the annular-shaped protection member is capable of blocking the heating layer from a plasma.

3. The electrostatic chuck according to claim 2, wherein:
the height of the uncompressed and undeformed annular-shaped protection member in the vertical direction is greater than or equal to the gap between the base and the insulating layer; and
when being assembled between the base and the insulating layer, the annular-shaped protection member is compressed and deformed to block the heating layer from the plasma.

4. The electrostatic chuck according to claim 3, wherein:
when the annular-shaped protection member is not compressed or deformed, a cross-sectional shape of the annular-shaped protection member in a plane where a central axis of the electrostatic chuck is located is a rectangle, a square, a trapezoid, a circle, or an ellipse.

5. The electrostatic chuck according to claim 4, wherein:
when the cross-sectional shape is the rectangle, the square, or the trapezoid, any two adjacent sides of the rectangle, the square, or the trapezoid adopt a rounded corner transition.

6. The electrostatic chuck according to claim 5, wherein:
a radius of the rounded corner ranges approximately between 1 mm and 3 mm.

7. The electrostatic chuck according to claim 3, wherein:
a cross-sectional shape of the annular-shaped protection member in a plane where a central axis of the electrostatic chuck is located is a circle; and
a height of an annular space formed between the outer peripheral wall of the heating layer, an upper surface of the base, and a lower surface of the insulating layer in an axial direction of the electrostatic chuck is smaller than about 90% of a diameter of the cross-sectional shape.

8. The electrostatic chuck according to claim 4, wherein:
the cross-sectional shape is the rectangle, the square, or the trapezoid; and
an outer annular surface of the annular-shaped protection member is a concave surface.

9. The electrostatic chuck according to claim 8, wherein:
a minimum thickness of the annular-shaped protection member in a radial direction is greater than or equal to about 80% of a maximum thickness of the annular-shaped protection member in the radial direction.

10. The electrostatic chuck according to claim 8, wherein:
the cross-sectional shape of the concave outer annular surface of the annular-shaped protection member is an arc, a diagonal line, or a folded line;
the folded line extends in the vertical direction and includes at least two line segments;
any two adjacent line segments of the at least two line segments are connected; and
an angle formed between any two adjacent line segments is an acute angle, a right angle, or an obtuse angle.

11. The electrostatic chuck according to claim 1, wherein:
the annular-shaped protection member includes an annular-shaped body;
the annular-shaped body is disposed between the base and the insulating layer, and surrounds the outer peripheral wall of the heating layer;
a height of the uncompressed and undeformed annular-shaped protection member in a vertical direction is greater than or equal to a gap between the base and the insulating layer;
at least one annular-shaped extension portion is formed on an outer peripheral wall of the annular-shaped body;
when the number of the at least one annular-shaped extension portion is one, the annular-shaped extension portion extends upward on the outer peripheral wall of the annular-shaped body and covers an outer peripheral wall of the insulating layer with a top end of the annular-shaped extension portion not higher than an upper surface of the insulating layer, or extends downward on the outer peripheral wall of the annular-shaped body and covers an outer peripheral wall of the base; and
when the number of the at least one annular-shaped extension portion is two, an upper half of the annular-shaped extension portion extends upward on the outer peripheral wall of the annular-shaped body and covers the outer peripheral wall of the insulating layer with the top end thereof not higher than the upper surface of the insulating aye′ and a lower half of the annular-shaped extension portion extends downward on the outer peripheral wall of the annular-shaped body and covers the outer peripheral wall of the base.

12. The electrostatic chuck according to claim 1, wherein:
the annular-shaped protection member is made of a perfluoro rubber.

13. A plasma processing apparatus comprising a processing chamber, wherein:
an electrostatic chuck is configured inside the processing chamber; and
the electrostatic chuck includes:
a base;
a heating layer disposed on the base;
an insulating layer disposed on the heating layer; and
an annular-shaped protection member surrounding an outer peripheral wall of the heating layer and detachably disposed on an outer side of the heating layer, wherein an outer diameter of the heating layer is shorter than both an outer diameter of the base and an outer diameter of the insulating layer.

14. The plasma processing apparatus according to claim 13, wherein:
the annular-shaped protection member is elastic;
a height of the uncompressed and undeformed annular-shaped protection member in a vertical direction is greater than or equal to a gap between the base and the insulating layer; and
when being assembled between the base and the insulating layer, the annular-shaped protection member is capable of blocking the heating layer from a plasma.

15. The plasma processing apparatus according to claim 14, wherein:
the height of the uncompressed and undeformed annular-shaped protection member in the vertical direction is greater than or equal to the gap between the base and the insulating layer; and
when being assembled between the base and the insulating layer, the annular-shaped protection member is compressed and deformed to block the heating layer from the plasma.

16. The plasma processing apparatus according to claim 15, wherein:
when the annular-shaped protection member is not compressed or deformed, a cross-sectional shape of the annular-shaped protection member in a plane where a central axis of the electrostatic chuck is located is a rectangle, a square, a trapezoid, a circle, or an ellipse.

17. The plasma processing apparatus according to claim 16, wherein:
when the cross-sectional shape is the rectangle, the square, or the trapezoid, any two adjacent sides of the rectangle, the square, or the trapezoid adopt a rounded corner transition.

18. The plasma processing apparatus according to claim 13, wherein:
the annular-shaped protection member includes an annular-shaped body;
the annular-shaped body is disposed between the base and the insulating layer, and surrounds the outer peripheral wall of the heating layer;
a height of the uncompressed and undeformed annular-shaped protection member in a vertical direction is greater than or equal to a gap between the base and the insulating layer;
at least one annular-shaped extension portion is formed on an outer peripheral wall of the annular-shaped body;
when the number of the at least one annular-shaped extension portion is one, the annular-shaped extension portion extends upward on the outer peripheral wall of the annular-shaped body and covers an outer peripheral wall of the insulating layer with a top end of the annular-shaped extension portion not higher than an upper surface of the insulating layer, or extends downward on the outer peripheral wall of the annular-shaped body and covers an outer peripheral wall of the base; and
when the number of the at least one annular-shaped extension portion is two, an upper half of the annular-shaped extension portion extends upward on the outer peripheral wall of the annular-shaped body and covers the outer peripheral wall of the insulating layer with the top end thereof not higher than the upper surface of the insulating layer, and a lower half of the annular-shaped extension portion extends downward on the outer peripheral wall of the annular-shaped body and covers the outer peripheral wall of the base.
